(19) United States
(12) Patent Application Publication
(10) Pub. No.: US 2015/0170944 A1
(43) Pub. Date: Jun. 18, 2015

(54) METHOD AND APPARATUS FOR THE ENGAGEMENT OF IC UNITS

(71) Applicant: Rokko Systems Pte Ltd, Singapore (SG)

(72) Inventor: Jong Jae Jung, Singapore (SG)

(73) Assignee: Rokko Systems Pte Ltd., Singapore (SG)

(21) Appl. No.: 14/414,450

(22) PCT Filed: Jul. 18, 2013
(86) PCT No.: PCT/SG13/00297

§ 371 Date: Jan. 13, 2015

(30) Foreign Application Priority Data
Jul. 20, 2012 (SG) 201205453-2

(51) Int. Cl. H01L 21/67

(52) U.S. Cl. CPC H01L 21/67132

(57) ABSTRACT

A picker station for receiving a frame of IC units, the picker station comprising: a unit picker assembly; a selectively movable ejector, arranged to be positioned beneath said frame, said ejector having two or more reciprocally movable ejector pins; wherein said ejector pins are arranged to simultaneously contact and lift two or more IC units out of said frame, with the unit picker assembly arranged to engage said two or more IC units on said ejector pins.

### FIELD OF THE INVENTION

The invention relates to the processing of integrated circuit (IC) units and in particular the processing of the individual unit having being diced from a substrate. Specifically, the invention relates to the use of picker assemblies for engaging and disengaging IC units as part of the processing flow.

### BACKGROUND

To meet the pricing demands of end users for new electronic products, manufacturers place downward pressure on the costs of manufacturing of individual chips. To this end, there is a need for continuous improvement in the speed and quality of the manufacture of IC units. UPH (Units Per Hour) is a direct measure of the speed of the manufacturing process and when waste is factored in, provides an indirect measure of quality also.

One such area for improvement involves the engagement of the IC units by unit pickers directly after singulation. In order to reduce the cost of manufacture of the IC units, standard sized substrates are subject to an increasing density of IC units moulded into the finite area. This has a direct effect on the clearance provided to unit pickers for engaging the IC units for the purpose of delivering the units further downstream along the processing path.

It is therefore an object of the present invention to provide a means of increasing the rate at which the units are processed and therefore having an influence on the UPH for the entire process.

### SUMMARY OF THE INVENTION

In a first aspect the invention provides a picker station for receiving a frame of IC units, the picker station comprising: a unit picker assembly; a selectively movable ejector, arranged to be positioned beneath said frame, said ejector having two or more reciprocally movable ejector pins; wherein said ejector pins are arranged to simultaneously contact and lift two or more IC units out of said frame, with the unit picker assembly arranged to engage said two or more IC units on said ejector pins.

In a second aspect the invention provides a method for engaging IC units from a frame, the method comprising the steps of: delivering a frame of IC units to a picker station having a unit picker assembly; selectively moving an ejector beneath said frame; projecting two or more reciprocally movable ejector pins, and consequently; simultaneously contacting and lifting two or more IC units from said frame, and so; engaging said IC units with the unit picker assembly.

By providing an ejector assembly capable of simultaneously lifting multiple IC units simultaneously it follows that the rate of processing the IC units is increased substantially. Consequently, the UPH for the process is correspondingly increased.

The number of ejector pins may be at least two. The ejector pins may be separated by a recess such that the pins eject alternating recesses. To this end, each ejector pin may be separated from the adjacent ejector pin by an IC recess. This may allow sufficient clearance in order to permit adjacent pickers to project down to the recesses without interference.

### BRIEF DESCRIPTION OF DRAWINGS

It will be convenient to further describe the present invention with respect to the accompanying drawings that illustrate possible arrangements of the invention. Other arrangements of the invention are possible and consequently, the particularity of the accompanying drawings is not to be understood as superseding the generality of the preceding description of the invention.

FIGS. 1A and 1B are various views of an ejector assembly according to one embodiment of the present invention;

FIGS. 2A and 2B are various view of an ejector assembly according to a further embodiment of the present invention and;

FIGS. 3A to 3C are elevation views of ejector pins according to a further embodiment of the present invention.

### DETAILED DESCRIPTION

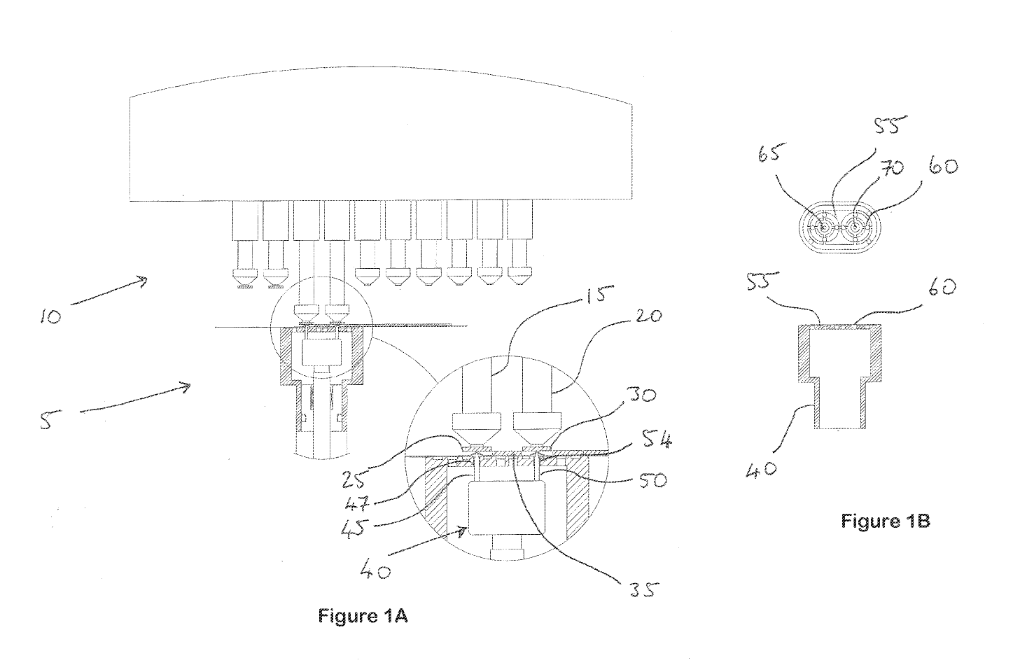

FIGS. 1A and 1B show a picker assembly 10 arranged to engage IC units 25, 30, 35, using extendable pickers 15, 20. The pickers 15, 20 are arranged to engage the IC units 25, 30 which have been lifted using an ejector assembly 5. The ejector assembly 5 includes a head 40 having ejector pins 45, 50 projecting there from. The ejector assembly 5 is movable so as to place the ejector pins 45, 50 directly below the recesses upon which the IC units are placed.

The ejector pins 45, 50 project through apertures 47, 54 beneath the IC units 25, 30 pushing them upwards so as to more easily engage with the pickers 15, 20.

In this case, the ejector assembly 5 includes two ejector pins 45, 50 which are spaced so as to engage alternating IC units 25, 30, leaving an intermediate IC unit 35 in place. After engagement by the pickers 15, 20, the ejector assembly 5 then moves along a rail (not shown) so as to position the ejector pins 45, 50 under the next IC units to be engaged.

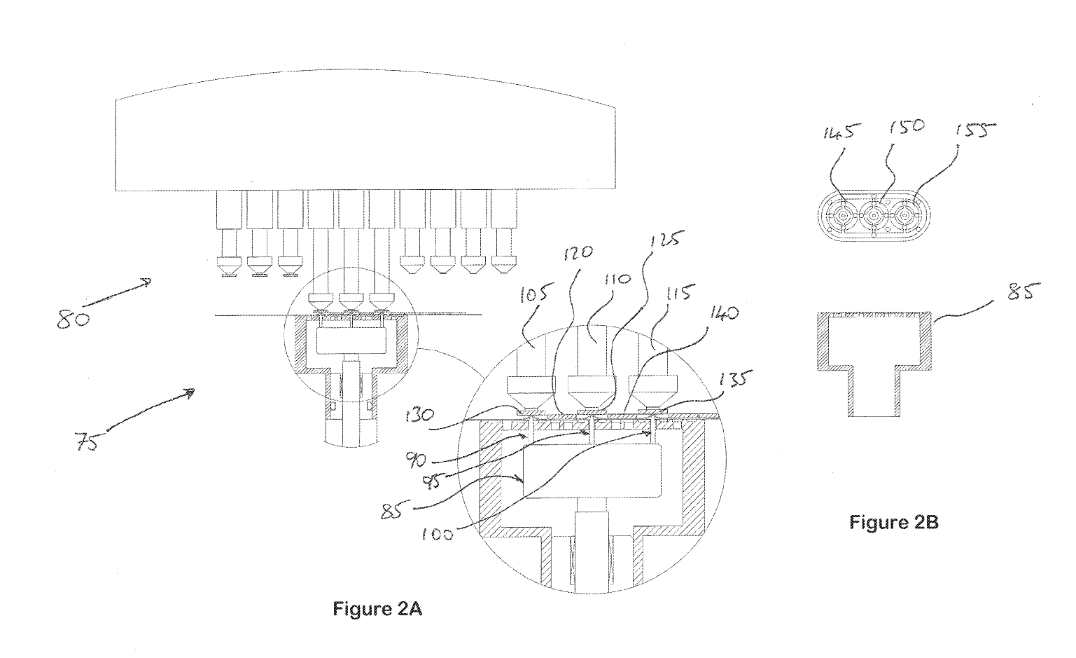

FIGS. 2A and 2B show an alternative embodiment of the present invention whereby an ejector assembly 75 is used with a picker assembly 80 for engaging three IC units 130, 125, 135, simultaneously. In this case the variation involves the addition of an additional ejector pin having three in total 90, 95, 100 projecting from the ejector head 85.

This permits three pickers 105, 110, 115 to extend to engage the respective IC units.

Similar to the embodiment of FIGS. 1A and 1B, the ejector pins 90, 95, 100 of FIGS. 2A and 2B are spaced so as to contact only alternating IC units 130, 125, 135 and leaving the intermediate IC units 120, 140 in place. This then allows the ejector assembly 75 to move along the rail so as to engage the remaining IC units.

It can be seen that the invention may be applicable to multiple ejector pins to be used simultaneously and so may have four, five or more ejector pins projecting from a single ejector head.

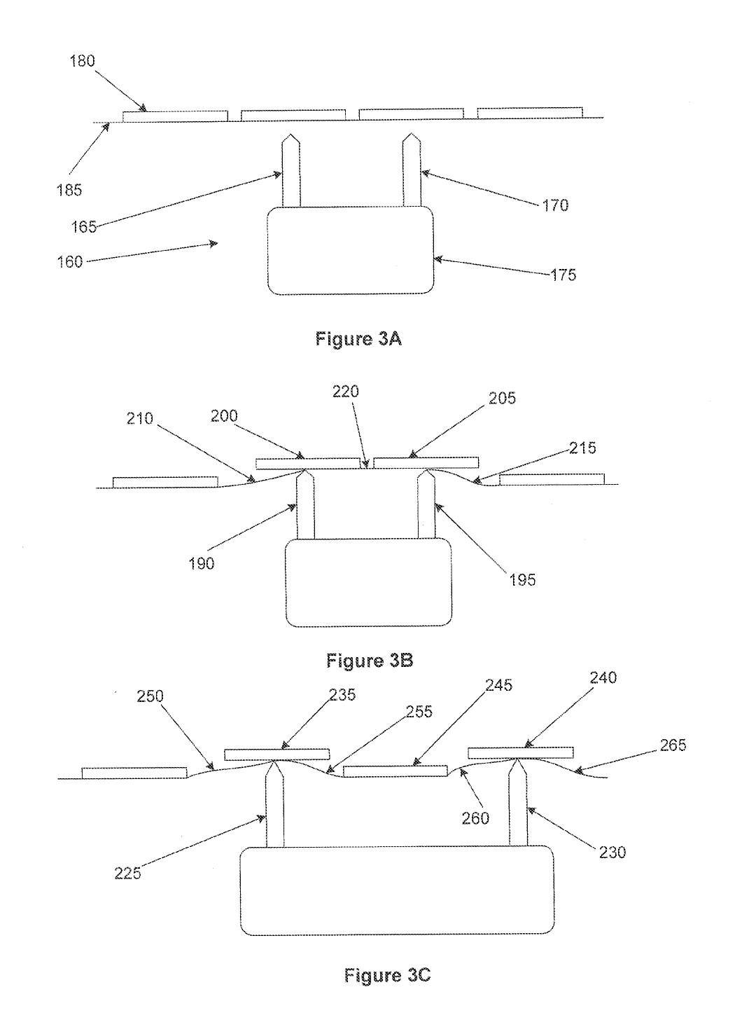

FIGS. 3A, 3B and 3C show various embodiments of the present invention. In particular FIG. 3A shows an ejector assembly 160 having an ejector head 175 and corresponding ejector pins 165, 170. The assembly 160 is currently arranged to contact a diced substrate of IC units 180. The IC units 180 are held in place by a backing layer 185 having an adhesive so as to ensure the position of the IC units 180.

FIG. 3B shows one embodiment of the present invention whereby the ejector pins 190, 195 have the same spacing, or pitch, as the IC units. That is, the ejector pins 190, 195 are positioned to contact and lift adjacent IC units 200, 205. Whilst not essential the benefits of having spaced ejector pins can be seen through the peeling and non-peeling of the backing layer. At the extreme edges of the IC units 200, 205 the backing layer peels 210, 215 due to the offset of the lifted IC units compared to the non-lifted units. However, as the adjacent IC units 200, 205 do not a relative offset, the backing layer between the IC units 220 remains in place. Whilst it may be possible for the pickers to pull the IC units 200, 205 from the backing material, it may not come off cleanly or may shift the position of the IC units whilst in engagement with the picker.

The embodiment shown in FIG. 3C shows the benefit gained by having the ejector pins 225, 230 spaced so as to leave an intermediate IC unit 245 in place, and so have a spacing equal to twice the pitch (centre to centre distance) of said IC units. Here, the ejector pins 225, 230 contact two IC units 235, 240. The differential offset between the lifted IC units and the IC units left in place show clear peeling 250, 255, 260, 265 of the backing layer from the IC units. Thus the lifting of the IC units by the ejector pins not only provide clearance for the pickers to engage the IC units but also when intermediate IC units remain, this also assists in removal of the backing layer for easier engagement and removal by the pickers.

1. A picker station for receiving a frame of IC units, the picker station comprising:
a unit picker assembly;
a selectively movable ejector, arranged to be positioned beneath said frame, said ejector having two or more reciprocally movable ejector pins;
wherein said ejector pins are arranged to simultaneously contact and lift two or more IC units out of said frame, with the unit picker assembly arranged to engage said two or more IC units on said ejector pins.

2. The picker station according to claim 1 wherein said two or more ejector pins are in spaced relation equal to twice the pitch of said IC units within said frame.

3. The picker station according to claim 1 said ejector is selectively movable relative to the picker assembly.

4. The picker station according to claim 1 wherein there are two ejector pins.

5. The picker station according to claim 1 wherein there are three ejector pins.

6. The picker station according to claim 1 wherein the ejector is arranged to simultaneously lift alternating IC units from said frame.

7. A method for engaging IC units from a frame, the method comprising the steps of:
delivering a frame of IC units to a picker station having a unit picker assembly;
selectively moving an ejector beneath said frame;
projecting two or more reciprocally movable ejector pins, and consequently;
simultaneously contacting and lifting two or more IC units from said frame, and so;
engaging said IC units with the unit picker assembly.

8. The method according to claim 7, wherein the simultaneously contacting and lifting step includes simultaneously lifting alternating IC units from said frame.
